(19) United States
(12) Patent Application Publication
(10) Pub. No.: US 2005/0142881 A1
(43) Pub. Date: Jun. 30, 2005

(54) Mask and method of using the same

(75) Inventors: Chih Ta Teng, Hsinchu (TW); Hsing Tsun Liu, Hsinchu (TW)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Mosel Vitelic, Inc., Hsinchu (TW)

(21) Appl. No.: 10/899,879

(22) Filed: Jul. 26, 2004

(30) Foreign Application Priority Data
Dec. 30, 2003 (TW) 092137531

(51) Int. Cl. H01L 21/302; H01L 21/461

(52) U.S. Cl. 438/690

(57) ABSTRACT

A mask applied in the process of miniaturizing a structural device is disclosed. The mask comprises a plurality of layout pattern areas for defining layers of the structural device, wherein at least one layout pattern area is arranged on the mask in a regular rule. A method for exposure is also disclosed. First, a mask comprising a plurality of layout pattern areas for defining layers of the structural device is provided, wherein at least one layout pattern area is arranged on the mask in a regular rule. Then one of the layout pattern areas is selected and the other layout pattern areas are covered. Finally, the mask is aligned with a substrate and the exposure is performed to transfer the pattern of the selected layout pattern area to the substrate.

### CROSS-REFERENCES TO RELATED APPLICATIONS

This application claims priority from R.O.C. Patent Application No. 092137531, filed Dec. 30, 2003, the entire disclosure of which is incorporated herein by reference.

### BACKGROUND OF THE INVENTION

The present invention relates to a mask and its method of use, and more particularly to a mask and its method of use as applied to miniaturize a structural device, such as a semiconductor device, a microelectromechanical system (MEMS) device, and a biochip.

Photolithography has been broadly applied in a manufacturing process of integrated circuit to form patterns on a semiconductor wafer. Every layer pattern and doped region of a semiconductor device is determined by a photolithographic process. Accordingly, the difficulty of the manufacturing process is roughly inferred by the number or duration of photolithography procedures, or the number of masks employed in a manufacturing process of a semiconductor device. In addition, whether the integration of semiconductor device can go for a smaller line width is determined by the breakthrough and development of photolithography. Therefore, a photolithographic process plays a significant role in a manufacturing process of semiconductor devices.

A mask typically costs about several hundred thousand New Taiwan dollars, and a mask used for a 0.13 μm process can be over one million New Taiwan dollars. When manufacturing a semiconductor device, the layout pattern of every layer of a semiconductor device needs at least one mask. Take a power MOSFET as an example; if a semiconductor device has six layers of layout patterns for manufacturing, at least six masks are needed to produce it. Take a flash memory as an example; since a flash memory generally requires 22 to 24 layers of integrated circuits patterns, 22 to 24 masks are used. Therefore, the cost of masks is very high. A set of masks may cost several millions to several tens of millions. Therefore, for integrated circuits designers or integrated circuits manufacturers, how to reduce the cost of masks when developing and manufacturing a new product is an urgent problem to be solved.

### BRIEF SUMMARY OF THE INVENTION

Embodiments of the present invention reduce the number of masks used for developing or manufacturing a structural device, so as to lower the cost of masks. The aforementioned structural device can be a semiconductor device, a microelectromechanical system (MEMS) device, a biochip or other devices that can be produced by a semiconductor manufacturing process.

In specific embodiments, a mask comprises layout pattern areas utilized for defining layers of the aforementioned structural device, and the arrangement of the layout pattern areas on the mask will be described hereafter. A method of using the mask is related to the design of the arrangement of the layout pattern areas.

In accordance with an aspect of the present invention, a mask to be used in a process of forming a structural device comprises a plurality of layout pattern areas for defining a plurality of layers of the structural device. At least one of the plurality of layout pattern areas is arranged on the mask in a regular way. In some embodiments, at least two layout pattern areas are substantially identical in size. There is a space between any two adjacent layout pattern areas. At least one layout pattern area has a different pattern from another one of the layout pattern areas.

In accordance with another aspect of the invention, an exposure method comprises providing a mask comprising a plurality of layout pattern areas for defining a plurality of layers of a structural device, wherein at least one of the layout pattern areas is arranged on the mask in a regular rule; selecting one of the layout pattern areas and covering the other layout pattern areas; and aligning the mask with a substrate and performing an exposure to transfer a pattern of the selected layout pattern area to the substrate.

In some embodiments, the substrate is provided before providing the mask. In other embodiments, the substrate is provided after providing the mask. The substrate may comprise a photo-resist layer. The mask and the substrate are aligned in accordance with at least one alignment portion on the space. The mask and the substrate may be aligned in accordance with at least one alignment portion on the layout pattern area. The wavelength of the light source used for exposure may range from visible light to deep ultraviolet. The light source used for exposure may be a high-energy particle beam. The light source used for exposure may be an electron beam.

Although the mask is implemented in an exposure machine of existing art in specific embodiments, exposure methods that use the mask as described herein are within the scope of the present invention, regardless of how mechanical operations of machines or exposure manners (such as the light source) are changed.

### BRIEF DESCRIPTION OF THE DRAWINGS

FIG. 1 shows a schematic view of a mask according to a specific embodiment of the present invention;

FIG. 2 shows a schematic view of a mask applied to an exposure machine during an exposure process according to an embodiment of the present invention; and

FIG. 3 shows a flow chart of an exposure process using a mask according to an embodiment of the present invention.

### DETAILED DESCRIPTION OF THE INVENTION

A mask of the present invention can be applied to miniaturize a structural device, such as a semiconductor device, a microelectromechanical system (MEMS) device or a biochip. In the following embodiments, a semiconductor device is taken as an example to illustrate the present invention.

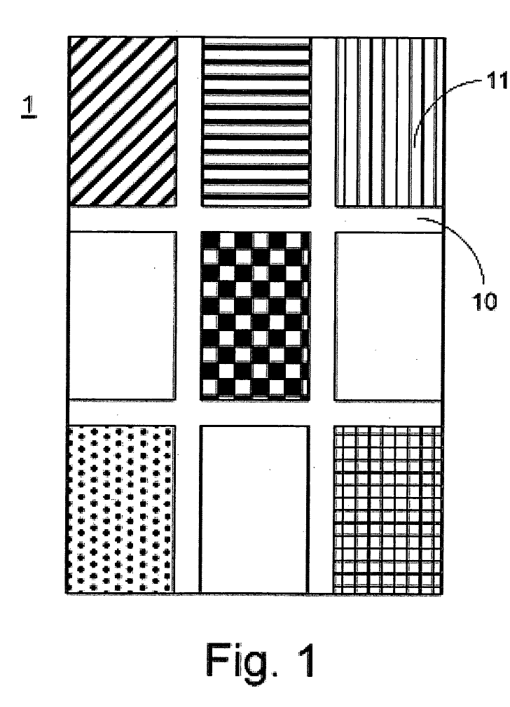

FIG. 1 shows a schematic view of a mask according to a specific embodiment of the present invention. As shown in FIG. 1, a mask 1 comprises a plurality of layout pattern areas 11 for defining layers of a semiconductor device (not shown), wherein at least one layout pattern area 11 is arranged on the mask 1 in a regular way. Some layout pattern areas shown in FIG. 1 are represented by different line features, such as straight lines, oblique lines or dots. The so-called “regular way” is not limited to line or row arrangements; the layout pattern areas 11 can be arranged in any form as long as they are arranged regularly or recurrently.

In some embodiments, for example, if the semiconductor device needs nine layout pattern areas 11, the layout pattern areas 11 can be arranged in the mask 1 as a 3 x 3 array.

The number of layout pattern areas 11 on a mask 1 is not restricted. In one embodiment, it is preferably not more than nine. In another embodiment, if a semiconductor device needs eighteen layout pattern areas, two masks can be used and each mask has nine layout pattern areas thereon. In still another embodiment, if the semiconductor device needs eighteen layout pattern areas, three masks can be used and each mask has six layout pattern areas thereon.

81 In some embodiments, for the arrangement of the layout pattern areas 11 on a mask 1, it is preferable to place a layout pattern area which has a relatively complex pattern or a pattern with a smaller critical size in the center of the mask. In one embodiment, it is preferable to place a layout pattern area with the most complex pattern and a smaller critical size in the center of the mask. In one embodiment, at least one layout pattern area 11 has a different pattern, or the patterns of all layout pattern areas are different, or the transparent portion of one layout pattern area is the opaque portion of another layout pattern area. In one embodiment, a mask 1 is a photo mask. The mask 1 is applied in an exposure machine.

In one embodiment, at least two layout pattern areas in a mask 1 are substantially identical in size. In another embodiment, it is preferable that all of the layout pattern areas are substantially identical in size. In some embodiments, there is a space 10 between any two adjacent layout pattern areas.

Take a power MOSFET as an example of semiconductor devices. The semiconductor device comprises at least six layers of circuits patterns. Therefore, at least six masks are needed for developing and manufacturing the semiconductor device according to the conventional method. However, according to the present embodiment, these layout patterns can be integrated into a single mask. Thus newly designed semiconductor devices can be developed and manufactured with only one mask. This greatly reduces the cost of masks.

Take a flash memory as another example of semiconductor devices. The semiconductor device generally comprises 22 to 24 layers of integrated circuits patterns. Therefore, 22 to 24 masks are needed for developing and manufacturing the semiconductor device according to the conventional method. However, according to the present embodiment, since each mask can comprise at most nine layout patterns, these 21 to 24 layout patterns can be integrated into three masks. Thus new designed semiconductor devices can be developed and manufactured with only three masks. This greatly reduces the cost of the masks.

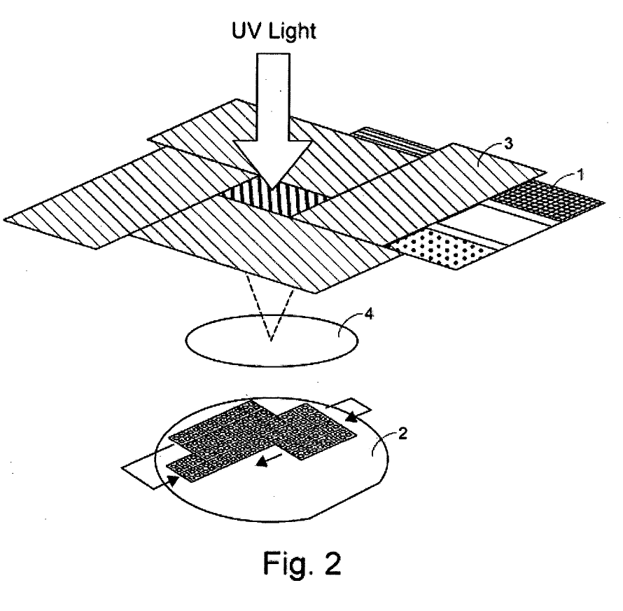

FIG. 2 shows a schematic view of a mask applied to an exposure machine during an exposure process according to another embodiment of the present invention. As shown in FIG. 2, after coated with a photo-resist layer and softly baked, a wafer 2 with the photo-resist layer (positive or negative photo-resist) is automatically loaded on a wafer platform of an exposure machine to be aligned and exposed. The dimensions of a wafer, object lens, mask or other elements in FIG. 2 are just shown for illustration, but do not represent the absolute or relative sizes of actual objects.

The wafer 2 or mask 1 in the exposure machine can be moved upwardly or downwardly according to the required focus scope. The wafer 2 and the mask 1 will be aligned with each other first, so that the pattern of the mask 1 can be accurately transferred to the appropriate position on the surface of the wafer 2. When the most optimal focus and alignment are achieved, for example, in one embodiment, a shading plate 3 is used to expose one specific layout pattern area of the mask 1 and cover the other layout pattern areas which are not in use.

The mechanical structure of the shading plate 3 shown in FIG. 2 is only one example. Different exposure machines may have different mechanical structures, so the shading plate can be in any form as long as it can be used to expose the desired layout pattern area and cover the others.

The exposure process is performed to irradiate light, such as ultraviolet, from the light source to the wafer 2 coated with the photo-resist layer through a specific layout pattern area and a projection lens 4. Afterward, the mask will be further moved to another position (as indicated by the arrows) to repeat the aforementioned steps of alignment and exposure until the whole wafer 2 is exposed completely.

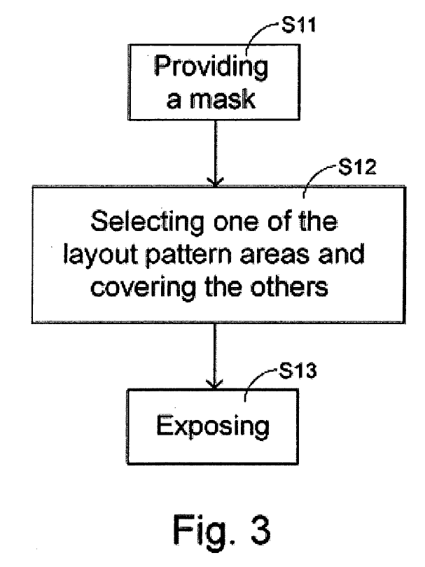

FIG. 3 shows a flow chart of an exposure process using a mask according to an embodiment of the present invention. As shown in FIG. 3, the exposure process using a mask comprises the following steps. First, a mask as described in the above embodiments is provided (step S11). Subsequently, one of the layout pattern areas is selected for exposing and the others are covered (step S12). Then the mask is aligned with a substrate for performing the exposure to transfer the pattern of the selected layout pattern area to the substrate (step S13). In some embodiments, the substrate is a wafer coated with the photo-resist layer.

In some other embodiments, a substrate can be provided before or after the step S11. It depends on the operation manner of exposure machines; in some exposure machines, the wafer is loaded first and the mask is loaded thereafter, while the loading sequence is reversed in some other exposure machines.

81 In some embodiments, at least one alignment portion (not shown) can be designed on a space 10 between any two adjacent layout pattern areas 11 of the mask 1, wherein the alignment portion can be designed as cross lines or other patterns, or patterns that are recognizable to exposure machines. Therefore, the mask 1 and the wafer 2 can be aligned in accordance with the alignment portion on the space 10. In other embodiments, at least one alignment portion (not shown) can be designed on the layout pattern area 11. Therefore, the mask 1 and the wafer 2 can be aligned in accordance with the alignment portion on the layout pattern area 11.

In an embodiment, the alignment portion is an alignment mark, which are visible patterns on the mask and the wafer to determine the position and the direction of the wafer. By the alignment step, the patterns of the mask can be accurately transferred to the appropriate position on the surface of the wafer.

The above-mentioned embodiments can be implemented on the exposure machines of NSR-2005i9C, NSR-2005i10C, NSR-2005i11D, NSR-2005i12D and NSR-2005i14E produced by Nikon, a Japanese company, all of which have light with a wavelength of 1 line.

In some embodiments, the wavelength of the light source employed for exposure ranges from visible light to deep ultraviolet. In another embodiment, the light source used for exposure can be a high-energy particle beam or an electron beam.

In addition, the uniform energy of ultraviolet is important to the exposure of the photo-resist. Each exposure and the exposure energy for each wafer preferably are highly reproducible. The exposure energy for photolithography can be controlled by an energy monitor to measure the intensity of ultraviolet on the surface of the wafer. The exposure energy is measured at different positions in the exposure field to calculate the percentage of the energy uniformity.

In conclusion, the present embodiment is to divide a mask into a plurality of pattern areas, and each pattern area is a layout pattern of each layer of a structural device. Therefore, when a structural device needs several masks to transfer the patterns to the wafer, the number of the masks to be used can be reduced, and thus the design cost of masks can be lowered.

The layout pattern of the present invention is not limited to a rectangle shown in FIG. 1. It can have other shapes and can be configured according to the circuits design, the mask design or the requirements of the manufacturing process. Furthermore, it is not necessary to fill up a mask with the layout patterns.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A mask to be used in a process of forming a structural device, the mask comprising a plurality of layout pattern areas for defining a plurality of layers of the structural device, wherein at least one layout pattern area of the plurality of layout pattern areas is arranged on the mask in a regular way.

2. The mask according to claim 1 wherein at least two layout pattern areas are substantially identical in size.

3. The mask according to claim 1 wherein there is a space between any two adjacent layout pattern areas.

4. The mask according to claim 1 wherein at least one layout pattern area has a different pattern from another one of the layout pattern areas.

5. The mask according to claim 1 wherein the structural device is a semiconductor device.

6. The mask according to claim 1 wherein the structural device is a microelectromechanical system (MEMS) device.

7. The mask according to claim 1 wherein the structural device is a biochip.

8. The mask according to claim 1 wherein the mask is to be used in an exposure apparatus.

9. An exposure method, comprising:
providing a mask comprising a plurality of layout pattern areas for defining a plurality of layers of a structural device, wherein at least one of the layout pattern areas is arranged on the mask in a regular rule;
selecting one of the layout pattern areas and covering the other layout pattern areas; and
aligning the mask with a substrate and performing an exposure to transfer a pattern of the selected layout pattern area to the substrate.

10. The method according to claim 9 wherein the substrate is provided before providing the mask.

11. The method according to claim 9 wherein the substrate is provided after providing the mask.

12. The method according to claim 9 wherein the substrate comprises a photo-resist layer.

13. The method according to claim 9 wherein there is a space between any two adjacent layout pattern areas of the mask.

14. The method according to claim 13 wherein the mask and the substrate are aligned in accordance with at least one alignment portion on the space.

15. The method according to claim 9 wherein the mask and the substrate are aligned in accordance with at least one alignment portion on the layout pattern area.

16. The method according to claim 9 wherein the wavelength of the light source used for exposure ranges from visible light to deep ultraviolet.

17. The method according to claim 9 wherein the light source used for exposure is a high-energy particle beam.

18. The method according to claim 9 wherein the light source used for exposure is an electron beam.
